(19) United States
(12) Patent Application Publication
(10) Pub. No.: US 2002/0135069 A1
(43) Pub. Date: Sep. 26, 2002

(54) Electroplating methods for fabricating microelectronic interconnects

(76) Inventors: Robert L. Wood, Cary, NC (US); Hong Shen, Raleigh, NC (US); Bruce W. Dudley, Apex, NC (US)

Correspondence Address: MYERS BIGEL SIBLEY & SAJOVEC, PO BOX 37428, RALEIGH, NC, 27627, US

(21) Appl. No.: 09/816,966

(22) Filed: Mar. 23, 2001

Related U.S. Application Data
(60) Provisional application No. 60/245,771, filed on Nov. 3, 2000.

(51) Int. Cl. H01L 23/48; H01L 23/52; H01L 29/40

(52) U.S. Cl. 257/758

(57) ABSTRACT

Microelectronic interconnections are fabricated by forming a via in a first face of a microelectronic substrate that extends only partially through the microelectronic substrate towards a second face thereof. The via includes a sidewall and a floor. An insulating layer is formed on the sidewall. A plating electrode is formed on the second face. Metal is electroplated in the via from the floor by passing plating current between the plating electrode and the floor through the microelectronic substrate therebetween. The substrate then is thinned at the second face to expose the metal that was electroplated. Electroplated metal through-substrate interconnections thereby may be fabricated.

### CROSS REFERENCE TO RELATED APPLICATION

This application claims the benefit of provisional application Ser. No. 60/245,771, filed Nov. 3, 2000, entitled Structure and Method for Forming Electrical Interconnections on a Microelectronic Substrate.

### FIELD OF THE INVENTION

This invention relates to microelectronic structures and fabrication methods therefor, and more particularly to microelectronic interconnect structures and fabrication methods therefor.

### BACKGROUND OF THE INVENTION

Microelectronic devices are widely used in consumer and commercial applications. Microelectronic devices include transistors, such as field effect transistors; optical devices, such as lasers and light emitting diodes; and microelectromechanical system (MEMS) devices, such as actuators and switches, that are formed in or on a microelectronic substrates. The microelectronic substrate generally is a silicon substrate, such as a bulk silicon substrate or a Silicon-on-Insulator (SOI) substrate. Devices may be fabricated in a microelectronic substrate in wafer form, after which the wafer is diced and separated into individual microelectronic substrates, often referred to as “chips”.

In designing, fabricating, packaging and/or using microelectronic devices, it may be desirable to form the microelectronic devices in or on a silicon substrate adjacent a first face thereof, and to convey electrical signal lines for external connections to a second face thereof, opposite the first face. The second face also may be referred to as the “backside” of the silicon substrate, and the first face that includes the microelectronic devices may be referred to as the “frontside”. By moving the external connection layer to the backside, more space may to be provided on the frontside for active devices. This can allow lower cost, higher yield and/or better reliability, and also can allow more compact arrangements of microelectronic devices to be designed and fabricated.

Unfortunately, it may be difficult to fabricate conductive, generally metal, connections that extend through the silicon substrate from the first face to the second face thereof. Specifically, although through-substrate interconnections may be provided in conventional plastic and/or ceramic printed wiring boards, it may be difficult to fabricate through-substrate interconnections for silicon substrates in a manner that is compatible with microelectronic device fabrication.

### SUMMARY OF THE INVENTION

Microelectronic interconnections may be fabricated, according to embodiments of the present invention, by forming a via in a first face of a microelectronic substrate that extends only partially through the microelectronic substrate towards a second face thereof. The via includes a sidewall and a floor. An insulating layer is formed on the sidewall. A plating electrode is formed on the second face. Metal is electroplated in the via from the floor by passing plating current between the plating electrode and the floor through the microelectronic substrate therebetween. The substrate then is thinned at the second face, for example by etching, grinding and/or polishing, to expose the metal that was electroplated. Electroplated metal through-substrate interconnections thereby may be fabricated.

Embodiments of the present invention can allow plating to be used to fabricate through-substrate interconnections that can provide low resistance backside connections. Moreover, unexpectedly, electroplating may be performed directly on a silicon surface, without the need for a conventional plating seed or plating base layer. Stated differently, according to embodiments of the present invention, metal is electroplated directly on a silicon substrate by exposing the silicon substrate to a plating solution and simultaneously passing plating current through the silicon substrate. More particularly, a via is formed in a first face of a silicon substrate that extends only partially through the silicon substrate towards a second face thereof. The via includes a silicon sidewall and a silicon floor. Metal then is directly electroplated on the silicon floor by passing current through the silicon substrate from the second face to the silicon floor.

Other embodiments of the present invention form the insulating layer on the sidewall by forming an insulating layer on the floor, on the sidewall and on the first face, and then removing at least some of the insulating layer from the floor, to expose at least a portion of the floor. Reactive ion etching may be used to remove at least some of the insulating layer from the floor. Wet etching also may be used in conjunction with the reactive ion etching.

According to other embodiments, at least one microelectronic device may be formed in or on the microelectronic substrate adjacent the first face. The at least one microelectronic device may be formed prior to forming the via, after thinning the substrate, or at any intermediate point in the above-described processes. Moreover, after thinning the substrate, external packaging connections may be formed on the exposed metal that was electroplated.

Microelectronic structures according to embodiments of the invention comprise a silicon substrate including a via therein that extends from a first face thereof only partially therethrough towards a second face thereof. The via includes a silicon sidewall and a silicon floor. An insulating layer is included on the silicon sidewall. A metal plug is in the via directly on the silicon floor. An electrode is provided on the second face. The insulating layer preferably comprises silicon dioxide and the electrode preferably comprises an unpatterned metal layer on the second face. At least one microelectronic device also may be provided in or on the silicon substrate adjacent the first face.

Other microelectronic structures according to embodiments of the invention comprise a silicon substrate including a via therein that extends therethrough from a first face thereof to a second face thereof. The via includes a silicon sidewall. An insulating layer is on the silicon sidewall, and a metal plug is included in the via. At least one microelectronic device is provided in or on the silicon substrate and electrically connected to the metal plug. In other embodiments, a mounting substrate is provided adjacent the silicon substrate and electrically connected to the metal plug. In yet other embodiments, at least one microelectronic device is provided in or on the silicon substrate adjacent the first face thereof and/or adjacent the second face thereof, and the mounting substrate is adjacent the second face of the silicon substrate. Accordingly, electroplating may be used to form through-substrate interconnections for a silicon substrate.

### BRIEF DESCRIPTION OF PREFERRED EMBODIMENTS

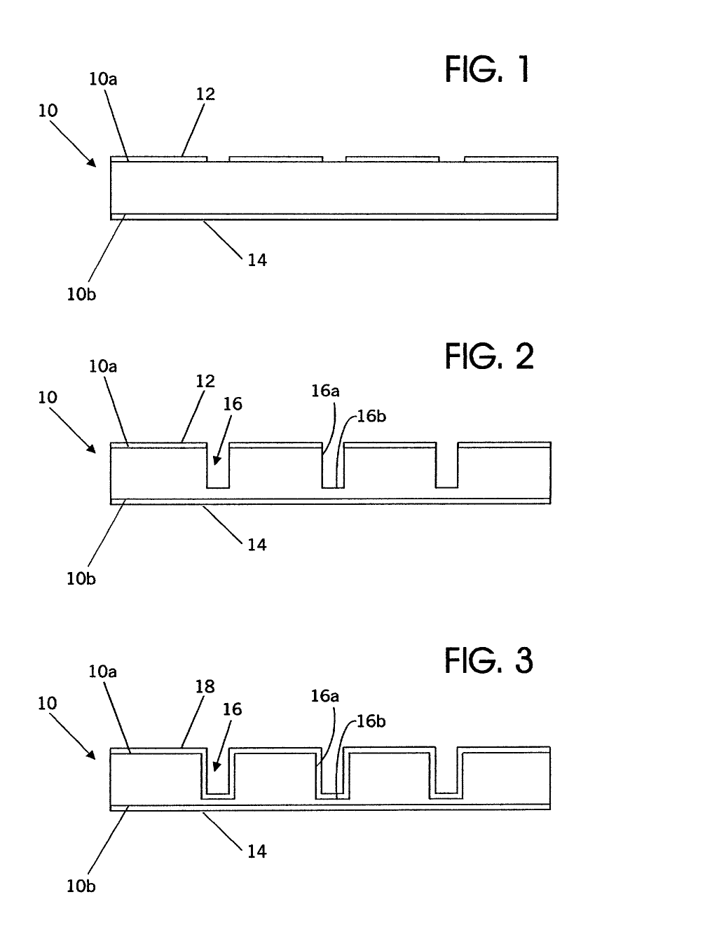

FIGS. 1-8 are cross-sectional views of microelectronic structures according to embodiments of the invention during intermediate fabrication steps according to embodiments of the invention.

### DETAILED DESCRIPTION OF THE PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

Finally, it should be noted that, in some alternative embodiments of the present invention, the operations noted in the Figures may occur out of the order noted in the Figures. For example, two Figures shown in succession may in fact be performed substantially concurrently or the Figures may sometimes be performed in the reverse order.

FIGS. 1-2 illustrate formation of a via in a first face of a microelectronic substrate that extends only partially through the microelectronic substrate towards the second face thereof, according to embodiments of the present invention. In particular, as shown in FIG. 1, the microelectronic substrate, preferably a silicon substrate 10, includes opposing first and second faces 10a and 10b, respectively. The first face 10a also may be referred to as the “frontside” and the second face 10b also may be referred to as the “backside” of the substrate 10. The silicon substrate 10 may be a bulk silicon semiconductor substrate or an SOI substrate. A via etch mask 12 is patterned on the first face 10a, for example using conventional photolithography. It will be understood that the via etch mask 12 may comprise a layer that already is used to pattern microelectronic devices or may be a separate layer that is used to mask the vias. As also shown in FIG. 1, an optional protective mask 14 also may be formed the second face 10b of the silicon substrate 10. The via etch mask 12 and/or the protective mask 14 may comprise conventional masking materials such as photoresist, silicon dioxide and/or silicon nitride.

Referring now to FIG. 2, at least one via 16 is formed in the first face 10a of the silicon substrate 10 that extends only partially through the silicon substrate 10 towards the second face 10b thereof. As shown, the via 16 includes a silicon sidewall 16a and a silicon floor 16b . The via 16 may be fabricated by performing a deep reactive ion etch and/or other anisotropic etch, to transfer the pattern of the via etch mask 12 part way into the substrate 10. Other conventional etching processes and/or other processes such as lift-off or selective epitaxial growth may be used. Preferably, the via extends at least half way through the thickness of the silicon substrate 10, and more preferably three quarters of the way through the thickness of the silicon substrate 10, but does not extend completely through the silicon substrate 10. By not extending all the way through the silicon substrate 10, conventional microelectronic processing may be used to fabricate microelectronic devices in or on the substrate. In particular, a substrate with vias that extend all the way through, from one face to another, may be difficult to process with vacuum-based wafer handling equipment.

In one example, the silicon substrate 10 is a conventional bulk silicon semiconductor wafer that is widely used in microelectronic fabrication, and which may be about 400 μm thick. The via may have a depth of at least about 200 μm and preferably about 300 μm, so that it extends at least half way, and preferably three quarters of the way, through the substrate.

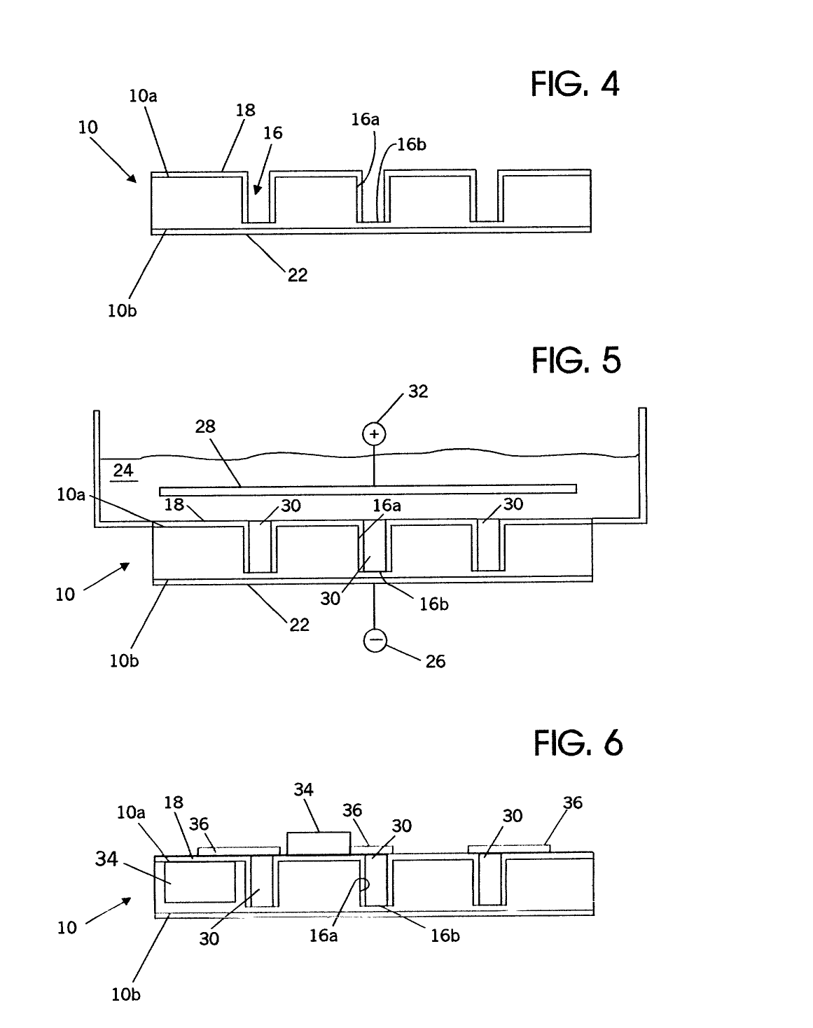

Referring now to FIGS. 3 and 4, an insulating layer is formed on the sidewalls 16a of the vias 16. More specifically, as shown in FIG. 3, a conformal insulating layer 18 is formed on the first face 10a, on the silicon sidewall 16a, and on the silicon floor 16b, for example by thermally oxidizing the first face 10a, the silicon sidewall 16a and the silicon floor 16b. Alternatively, a conformal layer of silicon dioxide and/or silicon nitride may be formed using chemical vapor deposition. In yet another alternative, non-conformal insulating layers may be formed and then etched, to provide a conformal layer.

Then, referring to FIG. 4, the insulating layer 18 is removed from the silicon floor 16b. For example, a reactive ion etch can be performed to remove the insulating layer 18 from the silicon floor 16b, as shown in FIG. 4. The reactive ion etch can allow the insulating layer 18 to remain on the silicon sidewall 16a and on the first face 10a, but can cleanly remove the insulating layer 18 from the silicon floor 16b, to thereby expose at least a portion, and preferably all of, the silicon floor 16b. During this removal process, some or all of the insulating layer 18 also may be removed from the first face 10a. However, the via etch mask 12 that remains may still mask the first face 10a. It also will be understood by those having skill in the art that a shadow mask process and/or other technique may be used to form a conformal insulating layer 18 on the silicon sidewall 16a, that exposes at least a portion of the silicon floor 16b. In other alternatives, the insulating layer may be formed to be thicker on the sidewalls 16a than on the floor 16b, for example due to the different crystallographic planes that may be exposed. Conventional wet (anisotropic) etching then may be used to expose the silicon floor 16b. Other techniques also may be used. Moreover, other insulating materials also may be used.

Still referring to FIG. 4, the protective mask 14 may be removed and a metal layer 22 is formed on the second face 10b. As will be described below, the metal layer 22 can function as a plating electrode during a subsequent plating process. The metal layer preferably is unpatterned. However, the metal layer also may be patterned, but preferably is present adjacent the silicon floor 16b. It also will be understood that the metal layer may be formed at other times during the fabrication steps of FIGS. 1-4.

Prior to forming the metal layer 22 on the second face 10b, a native oxide and/or any other protective/masking layers on the second face 10b may be removed, for example using conventional etching and/or cleaning techniques, to expose bare silicon. The metal layer 22 then may be blanket deposited on the second face 10b to form a conductive plane for electroplating. The metal layer 22 conveys the plating cathode current to the silicon floor 16b, allowing plating to initiate on the silicon floor 16b. Thus, the metal layer 22 can act as a “buried plating base” layer that is buried relative to the silicon floor 16b, but can convey plating current to the silicon floor 16b.

Referring now to FIG. 5, metal is electroplated (also referred to as electrodeposition) in the vias 16 from the silicon floor 16b, by passing plating current between the metal layer 22 and the silicon floor 16b, through the silicon substrate 10 therebetween. In particular, as shown in FIG. 5, the first face 10a is exposed to a plating solution 24, also referred to as a plating bath. The metal layer 22 acts as a first electrode, here a cathode, and is connected to a negative voltage 26. A second electrode 28 is provided in the plating solution 24, and is connected to a positive voltage 32, so that the second electrode 28 can function as an anode. Opposite connections also may be used and pulsed current and/or direct current may be used.

Electroplating takes place from the floor 16b by passing plating current between the first electrode 22 and the floor 16b through the microelectronic substrate 10 therebetween.

Thus, as was described above, the metal layer 22 may be regarded as a “buried plating base”, which can take the place of a plating base that is conventionally used when plating on silicon. There may be a small ohmic drop between the metal layer 22 and the silicon floor 16b, but this ohmic drop may be sufficiently small so as to allow plating to take place directly on the silicon floor 16b. For example, as was described above, the distance between the second face 10b and the silicon floor 16b may be about 100 μm or less. During plating, plating preferably does not take place from the silicon sidewall 16a due to the presence of the insulating layer 18 thereon. By reducing and preferably preventing plating from the sidewall 16a, a “key-holing” phenomenon may be prevented, wherein the plated metal may not completely fill the via 16 due to plating from the sidewall 16a that can close the via before plating from the floor 16b is completed. Alternatively, the plated metal may not completely fill the via 16.

An unexpected result of embodiments of the present invention is an ability to initiate electroplating directly on a silicon surface, rather than using a conventional plating seed layer or plating base. Plating of metals directly on silicon appears to be directly contrary to conventional wisdom. See, for example, U.S. Pat. No. 6,117,299 to Rinne et al. entitled Methods of Electroplating Solder Bumps of Uniform Height on Integrated Circuit Substrates and Lowenheim, Plating on Nonconductors, Chapter 28, Modern Electroplating, Third Edition, John Wiley & Sons, 1974.

In particular, silicon appears to be a poor choice as an electroplating substrate, due to its semiconducting properties and/or its tendency to spontaneously form a native oxide layer. Thus, in conventional plating, metals that are plated on silicon are generally preceded by a plating seed or plating base layer. For example, a thin conformal layer of copper, such as a layer of copper a few thousand Ångstroms thick, generally is deposited by evaporation and/or sputtering prior to plating a thick layer, for example, of tin. In embodiments of the invention, a plating base need not be formed on the floor 16b. By reducing and preferably eliminating the need for a plating seed layer, the plating of metal into the via holes may be simplified, and more natural integration of the through-hole process with conventional device fabrication may be provided, according to embodiments of the invention.

Still referring to FIG. 5, additional details of electroplating metal in the via 16 from the floor 16b according to embodiments of the invention now will be described. In particular, electroplating may take place by immersion in a plating bath or solution 24 with the first surface 10a exposed to the plating solution 24 and a cathode connection 26 made to the metal layer 22 on the second face 10b. A suitable plating material is low-stress nickel that can be plated from a conventional sulfamate bath, using a plating current density of about 10-20 mA/cm². Plating can occur selectively on the silicon floor 16b due to the inhibition of plating elsewhere by the insulating layer 18. Plating preferably is continued until a metal plug 30 is formed in the vias 16. Plating may be stopped when the metal plug 30 approaches (for example within a few tens of microns) or is coplanar with the first face 10a. Alternatively, the plating may continue until the plug extends onto the first face 10a and the substrate 10 may then be planarized using conventional techniques.

Referring now to FIG. 6, at least one microelectronic device 34 may be formed in and/or on the silicon substrate 10 adjacent the first face 10a, using conventional microelectronic device fabrication processes. As was described above, microelectronic devices can include electronic devices such as transistors; optoelectronic devices such as lasers or light-emitting diodes; and/or microelectromechanical system (MEMS) devices, such as actuators or switches. It also will be understood that the microelectronic device(s) may be formed, in whole or in part, prior to and/or during any of the preceding steps of FIGS. 1-5, so that embodiments of the invention may be integrated within a microelectronic device fabrication process.

As also shown in FIG. 6, at least one of the microelectronic devices 34 is connected to the plugs 30 using conventional metallization, including single level and/or multi-level metallization and/or other conventional techniques, to form at least one electrode 36 that routes microelectronic signals from the microelectronic devices 34 to and from the plugs 30 in the vias 16. The metallization may be performed using conventional photolithography, lift-off and/or other conventional techniques. Moreover, other process steps can be applied to complete the fabrication of the microelectronic device. It is preferable that these subsequent process steps not exceed temperatures of about 250° C., because higher temperatures may cause stress in the silicon substrate 10 due to the thermal mismatch with the plugs 30.

Accordingly, microelectronic structures according to embodiments of the invention include a silicon substrate 10 including a via 16 therein that extends from a first face 10a thereof, only partly therethrough towards a second face 10b thereof. The via 16 includes a silicon sidewall 16a and a silicon floor 16b. An insulating layer 18 is on the silicon sidewall 16b. A metal plug 30 is in the via directly on the silicon floor 16b. An electrode 36 is on the second face 10b.

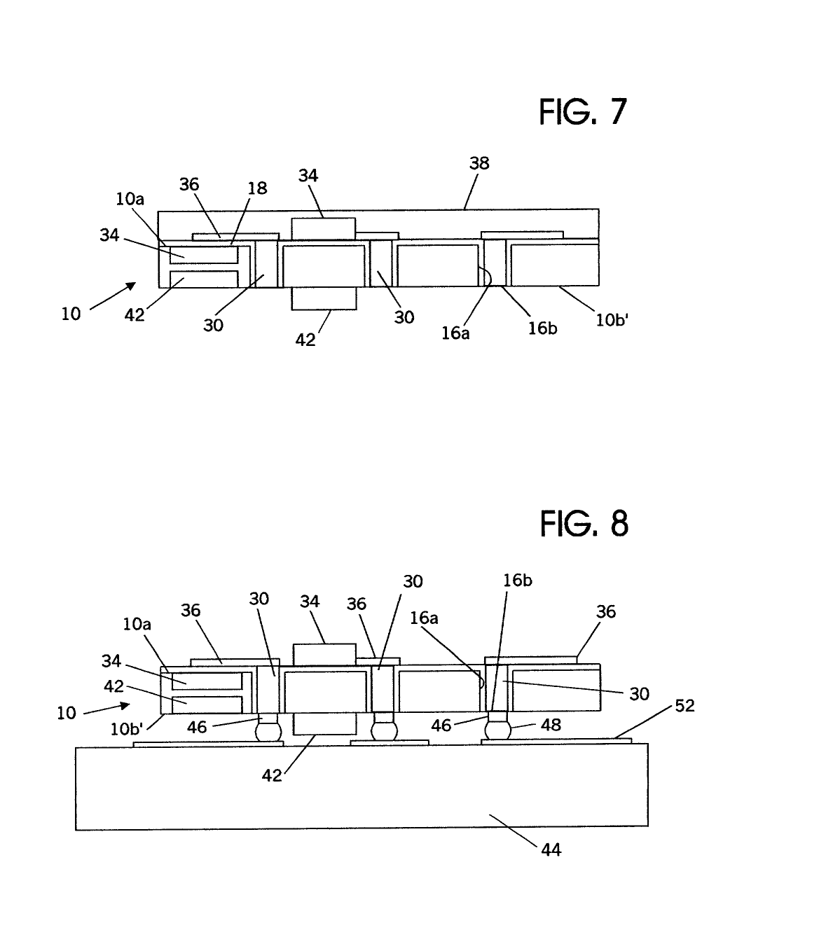

Referring now to FIG. 7, the substrate 10 is thinned at the second face 10b to expose the metal plug 30 that was electroplated. More particularly, as shown in FIG. 7, a protective layer 38, such as photoresist, dicing tape, silicon dioxide and/or silicon nitride, may be formed on the first face 10a, and the second face 10b may be thinned to expose the metal plugs 30 that were electroplated, and thereby form a thin second face 10b′. Thinning may take place using conventional backgrinding, optionally followed by polishing. Chemical etching, chemical-mechanical polishing and/or other conventional techniques also may be used to expose the metal plug 30. The amount of backgrinding, etching and/or chemical-mechanical polishing may be determined by the depth of the original via 16 in FIG. 2. In the example used in FIG. 2, about 100 μm may be ground from the second face 10b, to expose the metal plug 30. Polishing of the thin second face 10b′ may be performed where further processing of the thin second face 10b′ is desired. As also shown in FIG. 7, at least one optional second microelectronic device 42 may be formed in or on the thin second face 10b′ on the silicon substrate 10.

Accordingly, other microelectronic structures according to embodiments of the invention include a silicon substrate 10 including a via 16 therein that extends therethrough from a first face 10a thereof to a second face 10b′ thereof. The via 16 includes a silicon sidewall 16a. An insulating layer 18 is on the silicon sidewall. A metal plug 30 is in the via 16. At least one microelectronic device 36 and/or 42 is in or on the silicon substrate 10 and electrically connected to the metal plug 30.

Referring now to FIG. 8, the structure of FIG. 7 may be further packaged on a mounting substrate using conventional techniques. In particular, a mounting substrate 44 which may be a circuit board, an interposer and/or other mounting substrate, is located adjacent the thinned second face 10b′, and is attached thereto using conventional UnderBump Metallurgy (UBM) 46, solder bumps 48 and/or metallization 52. The formation of a UBM layer 46, solder bumps 48 and metallization 52 are well known to those having skill in the art and need not be described further herein. Other conventional packaging techniques including surface mount and/or ball grid array, may be used to attach the silicon substrate 10 to a mounting substrate 44. It also will be understood that the first face 10a may be attached to a mounting substrate 44, and both the first and thin second faces 10a and 10b′ may be attached to separate mounting substrates 44.

Accordingly, embodiments of the present invention can provide methods and structures for fabrication of plated through-holes that are electrically isolated from each other and from the silicon substrate itself. These plated through-holes can be connected to conductor traces within and/or on the silicon substrate 10, as well as external to the silicon substrate 10 through the thin second face 10b ′ of the substrate. The metal plugs 30 thus formed can be interconnected with patterned metal electrodes 36 on the first face 10a and/or the thin second face 10b ′, to provide connection to the active devices, and by solder bumps 48 and/or other conventional interconnection on the thin second face 10b′ and/or on the first face 10a, for routing signals external of the silicon substrate 10.

Embodiments of the invention therefore can convey electrical signals to the second face 10b of the silicon substrate, so that higher input/output density may be provided. Electrical, electromechanical and/or electro-optic fill-factors on the active first face 10a of the silicon substrate 10 thereby may be increased. Moreover, the plugs 30 may be fabricated with plated metal, to thereby allow a low resistance electrical interconnection path to be provided, and allow good isolation between conducting lines and from the substrate. Embodiments of the present invention can be integrated with other microelectronic fabrication processes, as well as with conventional packaging techniques, such as solder bumps 48. Moreover, embodiments of the invention can allow packaging of the silicon substrate through backside connections, so that frontside contacts may be reduced or eliminated. This may be particularly advantageous for MEMS devices that are formed on the first face 10a.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method of fabricating a microelectronic interconnection comprising:
forming a via in a first face of a microelectronic substrate that extends only partially through the microelectronic substrate towards a second face thereof, the via including a sidewall and a floor;
forming an insulating layer on the sidewall;
forming a plating electrode on the second face;
electroplating metal in the via from the floor by passing plating current between the plating electrode and the floor through the microelectronic substrate therebetween; and
thinning the substrate at the second face to expose the metal that was electroplated.

2. A method according to claim 1 wherein the forming an insulating layer comprises:
forming an insulating layer on the floor, on the sidewall and on the first face; and
removing at least some of the insulating layer from the floor to expose at least a portion of the floor.

3. A method according to claim 1:
wherein the forming a via is preceded by forming at least one microelectronic device in or on the microelectronic substrate, adjacent the first face; and
wherein the thinning the substrate is followed by forming an external packaging connection on the exposed metal that was electroplated.

4. A method according to claim 1 wherein the thinning the substrate is followed by:
forming at least one microelectronic device in or on the microelectronic substrate, that is electrically connected to the metal in the via; and
forming an external packaging connection on the microelectronic substrate that are electrically connected to the metal in the via.

5. A method according to claim 1 wherein the plating electrode is a first plating electrode and wherein the electroplating comprises:
exposing the first face to a plating solution including therein a second plating electrode; and
applying a plating voltage across the first and second electrodes to electroplate the metal in the via from the floor.

6. A method according to claim 1 wherein the electroplating comprises electroplating the metal directly on the floor.

7. A method according to claim 1 wherein the microelectronic substrate is a silicon semiconductor substrate.

8. A plating method comprising:
electroplating metal directly on a silicon substrate by exposing the silicon substrate to a plating solution and simultaneously passing plating current through the silicon substrate.

9. A plating method according to claim 8:
wherein the electroplating is preceded by forming a via in a first face of the silicon substrate that extends only partially through the silicon substrate towards a second face thereof, the via including a silicon sidewall and a silicon floor; and
wherein the electroplating comprises electroplating metal directly on the silicon floor by passing plating current through the silicon substrate, from the second face to the silicon floor.

10. A plating method according to claim 9 wherein the following is performed between the forming a via and the electroplating:
coating the silicon sidewall with an insulating layer.

11. A microelectronic structure comprising:
a silicon substrate including a via therein that extends from a first face thereof only partially therethrough towards a second face thereof, the via including a silicon sidewall and a silicon floor;
an insulating layer on the silicon sidewall;
a metal plug in the via directly on the silicon floor; and
an electrode on the second face.

12. A microelectronic structure according to claim 11 wherein the insulating layer comprises silicon dioxide.

13. A microelectronic structure according to claim 11 wherein the electrode comprises an unpatterned metal layer on the second face.

14. A microelectronic structure according to claim 11 further comprising at least one microelectronic device in or on the silicon substrate adjacent the first face.

15. A microelectronic structure according to claim 11 wherein the metal plug is an electroplated metal plug.

16. A microelectronic structure comprising:
a silicon substrate including a via therein that extends therethrough from a first face thereof to a second face thereof, the via including a silicon sidewall;
an insulating layer on the silicon sidewall;
a metal plug in the via; and
at least one microelectronic device in or on the silicon substrate and electrically connected to the metal plug.

17. A microelectronic structure according to claim 16 wherein the metal plug is an electroplated metal plug.

18. A microelectronic structure according to claim 16 further comprising a mounting substrate adjacent the silicon substrate and electrically connected to the metal plug.

19. A microelectronic structure according to claim 18 wherein the at least one microelectronic device is in or on the silicon substrate adjacent the first face thereof and wherein the mounting substrate is adjacent the second face thereof.

20. A microelectronic structure according to claim 19 wherein the at least one microelectronic device is at least one first microelectronic device, the structure further comprising at least one second microelectronic device in or on the silicon substrate adjacent the second face thereof.
